(19) United States
(12) Patent Application Publication
(10) Pub. No.: US 2023/0046449 A1
(43) Pub. Date: Feb. 16, 2023

(54) PHOTOELECTRIC CONVERSION MODULE

(71) Applicant: NITTO DENKO CORPORATION, Osaka (JP)

(72) Inventors: Kazuaki SUZUKI, Osaka (JP); Naoyuki TANAKA, Osaka (JP); Naoto KONEGAWA, Osaka (JP)

(73) Assignee: NITTO DENKO CORPORATION, Osaka (JP)

(21) Appl. No.: 17/794,143

(22) PCT Filed: Jan. 19, 2021
(86) PCT No.: PCT/JP2021/001643

§ 371 Date: Jul. 20, 2022

(30) Foreign Application Priority Data
Jan. 23, 2020 (JP) 2020-008904

(51) Int. Cl. G02B 6/42

(52) U.S. Cl. CPC G02B 6/4272; G02B 6/4274

(57) ABSTRACT

Provided is optical module as a photoelectric conversion module that includes a photoelectric hybrid board, a light-receiving/emitting element, a driving element, and a heat dissipating sheet. The light-receiving/emitting element and the driving element are mounted on one surface in a thickness direction of the photoelectric hybrid board. The heat dissipating sheet is in contact with the light-receiving/emitting element and the driving element from a side opposite to the photoelectric hybrid board. The driving element has a greater height above the photoelectric hybrid board than the light-receiving/emitting element.

### TECHNICAL FIELD

The present invention relates to a photoelectric conversion module.

### BACKGROUND ART

In an optical transmission system using an optical signal for signal transmission between electronic devices or the like, a photoelectric conversion module is used for conversion (photoelectric conversion) between the optical signal and an electrical signal at the time of transmission and reception of signals by a device or the like. The photoelectric conversion module includes, for example, a photoelectric hybrid board having both an electrical wiring and an optical wiring, and light-receiving/emitting elements (light-receiving element, light-emitting element) and various driving elements for the light-receiving/emitting elements mounted thereon. The art relating to the photoelectric conversion module is, for example, described in Patent Document 1 below.

### CITATION LIST

### Patent Document

Patent Document 1: Japanese Unexamined Patent Publication No. 2018-97263

### SUMMARY OF THE INVENTION

### Problem to be Solved by the Invention

During the photoelectric conversion by the photoelectric conversion module, the light-receiving/emitting element and the driving element generate heat. The amount of generated heat of the driving element is larger than that of the light-receiving/emitting element, and in the photoelectric conversion module, the heat generation of the driving element may contribute to a temperature rise of the light-receiving/emitting element. In particular in a case where the light-receiving/emitting element and the driving element are disposed close to each other on the same plane of the photoelectric hybrid board from the viewpoint of miniaturization of the photoelectric conversion module, the heat generation of the driving element tends to raise the temperature of the light-receiving/emitting element. An excessive temperature rise of the light-receiving/emitting element may lead to malfunction of the light-receiving/emitting element, which is undesirable. Therefore, the photoelectric conversion module requires heat dissipation measures for the elements, for example, under the size limitation from the viewpoint of miniaturization.

Further, in the photoelectric conversion module, the light-receiving/emitting element tends to be more fragile than the driving element, and is easily damaged. Therefore, the heat dissipation measures for heat generating elements such as the light-receiving/emitting elements are required to be realized while suppressing damage to the light-receiving/emitting elements.

The present invention provides a photoelectric conversion module suitable for realizing excellent heat dissipation of elements while suppressing damage to a light-receiving/emitting element.

### Means for Solving the Problem

The present invention [1] includes a photoelectric conversion module including a photoelectric hybrid board; a light-receiving/emitting element and a driving element mounted on one surface in a thickness direction of the photoelectric hybrid board; and a heat dissipating sheet contacting the light-receiving/emitting element and the driving element from a side opposite to the photoelectric hybrid board, wherein the driving element has a greater height above the photoelectric hybrid board than the light-receiving/emitting element.

In the photoelectric conversion module of the present invention, as described above, the heat dissipating sheet contacts the light-receiving/emitting element and the driving element mounted above one surface in the thickness direction of the photoelectric hybrid board from the side opposite to the photoelectric hybrid board. When these elements generate heat, such a configuration is suitable for releasing the heat to the outside the element by the heat dissipating sheet, and accordingly, outside the photoelectric conversion module through the heat dissipating sheet. In a module casing, the present photoelectric conversion module may be disposed so that the heat dissipating sheet is interposed between a predetermined inner wall surface of the casing and the light-receiving/emitting and the driving elements above the photoelectric hybrid board, and the sheet is pressed against each element. This allows the heat dissipating sheet to contact the light-receiving/emitting element and the driving element to perform a heat dissipating function.

Further, in the photoelectric conversion module of the present invention, as described above, the driving element has a greater height above the photoelectric hybrid board than the light-receiving/emitting element. Therefore, the pressing force of the heat dissipating sheet, which is pressed against the light-receiving/emitting element and the driving element above the photoelectric hybrid board in the above-described state in the module casing, is relatively strong with respect to the driving element, and relatively weak with respect to the light-receiving/emitting element. Such a configuration is suitable for realizing heat dissipation of the light-receiving/emitting element by the heat dissipating sheet while suppressing damage to the light-receiving/emitting element, and for realizing a high heat dissipation efficiency for the driving element by the heat dissipating sheet. That is, the photoelectric conversion module of the present invention is suitable for realizing excellent heat dissipation of the light-receiving/emitting element and the driving element while suppressing damage to the light-receiving/emitting element.

The present invention [2] includes the photoelectric conversion module described in the above-described [1] further including a first bump interposed between the photoelectric hybrid board and the light-receiving/emitting element and electrically connecting them, and a second bump interposed between the photoelectric hybrid board and the driving element and electrically connecting them, wherein the second bump has a greater height above the photoelectric hybrid board than the first bump.

Such a configuration is suitable for adjusting each height of the light-receiving/emitting element and the driving element above the photoelectric hybrid board at a higher degree of freedom depending on each height of the first bump and the second bump regardless of each thickness of the light-receiving/emitting element and the driving element. Such a configuration is suitable for making the height of the driving element greater than the height of the light-receiving/emitting element above the photoelectric hybrid board, even though the thickness of the light-receiving/emitting element is, for example, the thickness of the driving element or more.

The present invention [3] includes the photoelectric conversion module described in the above-described [1] or [2], wherein the heat dissipating sheet has an Asker C hardness of 60 or less.

The heat dissipating sheet having such a degree of softness is suitable for ensuring followability and adhesion with respect to the light-receiving/emitting element and the driving element having different heights above the photoelectric hybrid board, and accordingly, suitable for realizing both damage suppression of the light-receiving/emitting element and a high heat dissipation efficiency for the driving element.

### BRIEF DESCRIPTION OF THE DRAWINGS

FIGS. 1A-1C show one embodiment of a photoelectric conversion module of the present invention:

FIG. 1A illustrating a plan view of the photoelectric conversion module,

FIG. 1B illustrating a plan view of the photoelectric conversion module in which a first cover member is removed, and

FIG. 1C illustrating a bottom view of the photoelectric conversion module in which a second cover member is removed.

FIG. 2 shows a side cross-sectional view of the photoelectric conversion module shown in FIGS. 1A-1C.

FIG. 3 shows a partially enlarged view of FIG. 2.

FIGS. 4A and 4B show a first cover member and a second cover member:

FIG. 4A illustrating a bottom view of the first cover member and

FIG. 4B illustrating a plan view of the second cover member.

FIG. 5 shows a side cross-sectional view of one modified example of the photoelectric conversion module shown in FIGS. 1A-1C in which a bump for a driving element is located higher than that for a light-receiving/emitting element above a photoelectric hybrid board.

FIG. 6 shows a side cross-sectional view of another modified example (embodiment further including a protruding portion) of the photoelectric conversion module shown in FIGS. 1A-1C.

FIG. 7 shows a side cross-sectional view of another modified example (embodiment further including a protruding portion and a heat dissipating layer in contact therewith) of the photoelectric conversion module shown in FIGS. 1A-1C.

### DESCRIPTION OF EMBODIMENTS

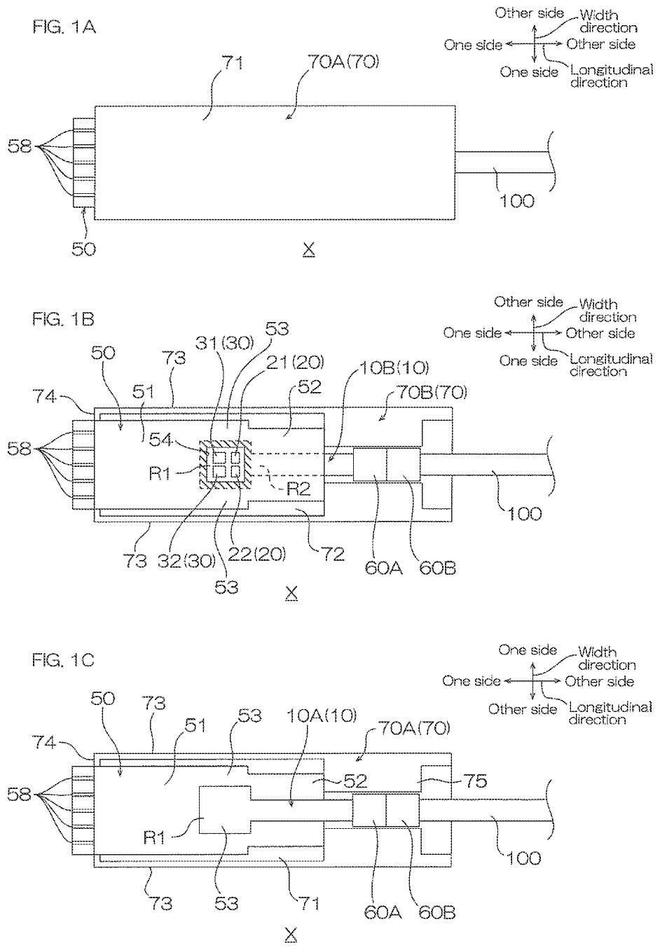

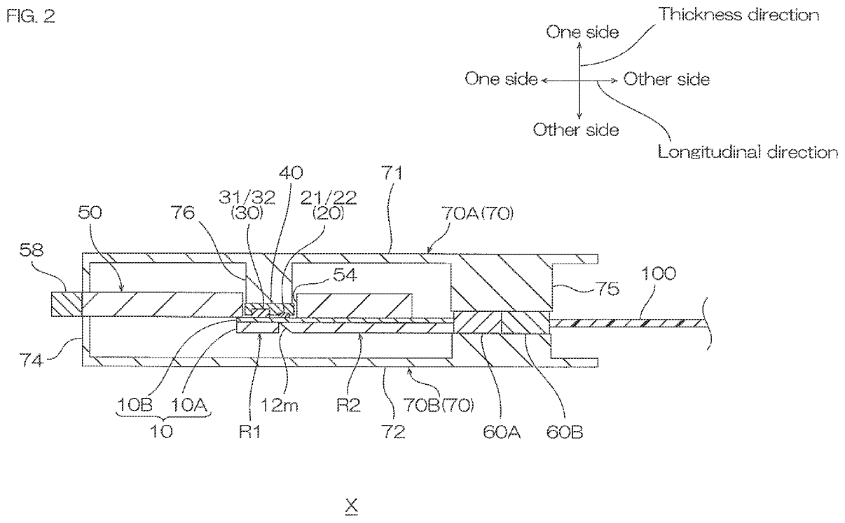

FIGS. 1A to 3 show an optical module X which is one embodiment of a photoelectric conversion module of the present invention. In the present embodiment, the optical module X includes a photoelectric hybrid board 10, a light-receiving/emitting element 20, a driving element 30, a heat dissipating sheet 40, a printed wiring board 50, a connector 60A, and a casing 70 for housing them. In FIGS. 1A to 2, the optical module X is represented as an embodiment connected to an optical fiber cable 100 having a connector 60B at its end. The optical module X is an element to be connected to a receptacle provided in a device which transmits and receives signals through the optical fiber cable 100. In the present embodiment, the optical module X is configured to be a transmitting and receiving module (i.e., an optical transceiver) having both a transmission function of converting an electrical signal from a device to an optical signal and outputting it to the optical fiber cable 100, and a receiving function of converting an optical signal from the optical fiber cable 100 to an electrical signal and outputting it to the device.

As shown in FIGS. 1A to 2, the optical module X has a generally flat plate shape extending long in one direction, and has a width in a direction perpendicular to a longitudinal direction thereof. Further, the optical module X has a thickness in a direction perpendicular to the longitudinal direction and a width direction.

The photoelectric hybrid board 10 has a generally flat plate shape extending long along the longitudinal direction of the optical module X. The photoelectric hybrid board 10 has a photoelectric conversion region R1 and an optical transmission region R2. The photoelectric conversion region R1 is disposed in one end in the longitudinal direction of the photoelectric hybrid board 10. The photoelectric conversion region R1 has a generally rectangular shape (specifically, square shape) in a bottom view shown in FIG. 1C. The optical transmission region R2 extends from an other side end in the longitudinal direction of the photoelectric conversion region R1 toward the other side in the longitudinal direction. The optical transmission region R2 has a generally rectangular shape in a bottom view shown in FIG. 1C. A length in the width direction of the optical transmission region R2 is shorter than that in the width direction of the photoelectric conversion region R1. A length in the longitudinal direction of the optical transmission region R2 is longer than that in the longitudinal direction of the photoelectric conversion region R1. An other side end in the longitudinal direction of the optical transmission region R2 is connected to the connector 60A.

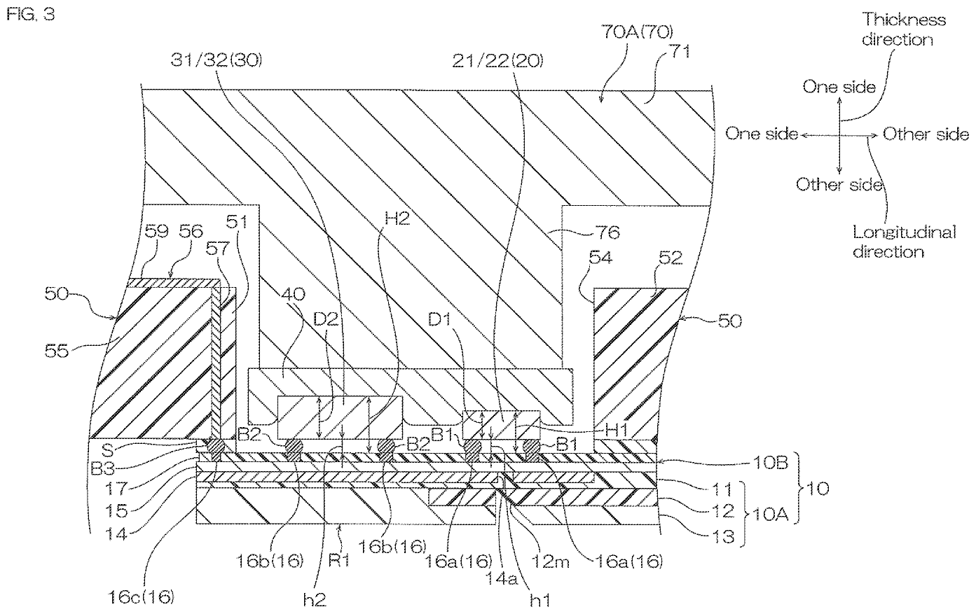

As shown in FIG. 3, the photoelectric hybrid board 10 includes an optical waveguide portion 10A and an electric circuit board 10B in order toward one side in the thickness direction. Specifically, the photoelectric hybrid board 10 includes the optical waveguide portion 10A, and the electric circuit board 10B disposed on one surface in the thickness direction of the optical waveguide portion 10A.

The optical waveguide portion 10A is disposed on the other surface in the thickness direction of the electric circuit board 10B. The optical waveguide portion 10A has a generally sheet shape extending in the longitudinal direction (the optical waveguide portion 10A extends over the photoelectric conversion region R1 and the optical transmission region R2). The optical waveguide portion 10A includes an under-cladding layer 11, a core layer 12, and an over-cladding layer 13 in order toward the other side in the thickness direction.

The under-cladding layer 11 is disposed on the other surface in the thickness direction of the electric circuit board 10B. The core layer 12 is disposed on the other surface in the thickness direction of the under-cladding layer 11. The core layer 12 is provided for each light-receiving/emitting element 20. The core layer 12 has a mirror surface 12m in one end in the longitudinal direction thereof. The mirror surface 12m is inclined at 45 degrees with respect to an optical axis of light propagating through the core layer 12, and an optical path is bent at 90 degrees by the mirror surface 12m. The over-cladding layer 13 covers the core layer 12 at the other side in the thickness direction of the under-cladding layer 11. The thickness of the optical waveguide portion 10A is, for example, 20 μm or more, and for example, 200 μm or less.

The core layer 12 forms an optical transmission path itself which has a higher refractive index than the under-cladding layer 11 and the over-cladding layer 13. Examples of a constituent material for the under-cladding layer 11, the core layer 12, and the over-cladding layer 13 include resin materials having transparency and flexibility such as epoxy resins, acrylic resins, and silicone resins, and from the viewpoint of transmissibility of the optical signal, preferably, epoxy resins are used.

The electric circuit board 10B is disposed on one surface in the thickness direction of the under-cladding layer 11. The electric circuit board 10B has a generally sheet shape extending in the longitudinal direction (the electric circuit board 10B extends over the photoelectric conversion region R1 and the optical transmission region R2). The electric circuit board 10B includes a metal support layer 14, a base insulating layer 15, a conductive layer 16, and a cover insulating layer 17 in order toward one side in the thickness direction.

As shown in FIG. 3, the metal support layer 14 is disposed in the photoelectric conversion region R1. The metal support layer 14 has a metal opening portion 14a. The metal opening portion 14a penetrates the metal support layer 14 in the thickness direction. The metal opening portion 14a overlaps the mirror surface 12m in a projection view in the thickness direction. The plurality of metal opening portions 14a are provided corresponding to a light emitting element 21 and a light receiving element 22 to be described later. Examples of a constituent material for the metal support layer 14 include metals such as stainless steel, 42-alloy, aluminum, copper-beryllium, phosphor bronze, copper, silver, nickel, chromium, titanium, tantalum, platinum, and gold. A thickness of the metal support layer 14 is, for example, 3 μm or more, preferably 10 μm or more, and for example, 100 μm or less, preferably 50 μm or less.

The base insulating layer 15 is disposed over the photoelectric conversion region R1 and the optical transmission region R2. The base insulating layer 15 is disposed on one surface in the thickness direction of the metal support layer 14. Further, the base insulating layer 15 closes one end in the thickness direction of the metal opening portion 14a. Examples of a constituent material for the base insulating layer 15 include resins such as polyimide. Further, the constituent material for the base insulating layer 15 has optical transparency. The thickness of the base insulating layer 15 is, for example, 2 μm or more, and for example, 35 μm or less.

The conductive layer 16 is disposed on one side in the thickness direction of the base insulating layer 15. The conductive layer 16 is disposed in the photoelectric conversion region R1 and includes a terminal 16a, a terminal 16b, a terminal 16c, and a wiring which is not shown. The terminal 16a is patterned corresponding to an electrode (not shown) of the light-receiving/emitting element 20. The terminal 16b is patterned corresponding to an electrode (not shown) of a driving element 30. The terminal 16c is patterned corresponding to a via 57 to be described later of the printed wiring board 50. The wiring which is not shown electrically connects the terminals 16a, 16b, and 16c. Examples of a constituent material for the conductive layer 16 include conductors such as copper. The thickness of the conductive layer 16 is, for example, 2 μm or more, and for example, 20 μm or less.

The cover insulating layer 17 is disposed on one surface in the thickness direction of the base insulating layer 15 so as to expose the terminals 16a, 16b, and 16c and cover the wiring which is not shown. The cover insulating layer 17 is disposed over the photoelectric conversion region R1 and the optical transmission region R2. The constituent material and the thickness of the cover insulating layer 17 are the same as those of the base insulating layer 15.

The thickness of the electric circuit board 10B is, for example, 15 μm or more, and for example, 200 μm or less. The ratio of the thickness of the metal support layer 14 to that of the electric circuit board 10B is, for example, 0.2 or more, preferably 0.5 or more, more preferably 0.8 or more, and for example, 1.2 or less. When the above-described ratio is the above-described lower limit or more, it is possible to improve the heat dissipation of the electric circuit board 10B.

The thickness of the photoelectric hybrid board 10 is, for example, 25 μm or more, preferably 40 μm or more, and for example, 500 μm or less, preferably 250 μm or less. The ratio of the thickness of the metal support layer 14 to that of the photoelectric hybrid board 10 is, for example, 0.05 or more, preferably 0.1 or more, more preferably 0.15 or more, and for example, 0.4 or less. When the above-described ratio is above the above-described lower limit, it is possible to improve the heat dissipation of the photoelectric hybrid board 10.

The photoelectric hybrid board 10 has flexibility. Specifically, the photoelectric hybrid board 10 has a tensile elastic modulus at 25° C. of, for example, below 10 GPa, preferably 5 GPa or less, and for example, 0.1 GPa or more. When the tensile elastic modulus of the photoelectric hybrid board 10 is below the above-described upper limit, it is possible to flexibly support the light-receiving/emitting element 20 and the driving element 30.

The light-receiving/emitting element 20 is the light emitting element 21 for converting an electrical signal into an optical signal, or the light receiving element 22 for converting an optical signal into an electrical signal, and is mounted on one surface in the thickness direction in the photoelectric conversion region R1 of the photoelectric hybrid board 10 (i.e., one surface in the thickness direction of the electric circuit board 10B). In the present embodiment, at least one light emitting element 21 and at least one light receiving element 22 are provided as the light receiving/emitting element 20. An electrode of the light-receiving/emitting element 20 (the light receiving element 21, the light emitting element 22) is bonded to the terminal 16a of the conductive layer 16 in the electric circuit board 10B through a bump B1 (first bump) to be electrically connected thereto. That is, the bump B1 is interposed between the photoelectric hybrid board 10 and the light-receiving/emitting element 20 to electrically connect them.

The thickness D1 of the light-receiving/emitting element 20 is, for example, 50 μm or more, preferably 100 μm or more, and for example, 500 μm or less, preferably 200 μm or less. The height h1 of the bump B1 is, for example, 3 μm or more, preferably 5 μm or more, and for example, 100 μm or less, preferably 50 μm or less. The ratio (D1/h1) of the thickness D1 to the height h1 is, for example, 0.5 or more, preferably 2 or more, and for example, 150 or less, preferably 20 or less.

The light emitting element 21 is, for example, a laser diode such as a vertical-cavity surface-emitting laser (VCSEL). A light emitting port (not shown) of the light emitting element 21 is disposed on the other surface in the thickness direction of the light emitting element 21. The light emitting port of the light emitting element 21 faces the mirror surface 12m through the metal opening portion 14a in the thickness direction. Thus, the light emitting element 21 is optically connected to the optical waveguide portion 10A.

The light receiving element 22 is, for example, a photodiode. Examples of the photodiode include PIN (p-intrinsic-n)-type photodiodes, MSM (Metal Semiconductor Metal) photodiodes, and avalanche photodiodes. A light receiving port (not shown) of the light receiving element 22 is disposed on the other surface in the thickness direction of the light receiving element 22. The light receiving port of the light receiving element 22 faces the mirror surface 12m through the metal opening portion 14a in the thickness direction. Thus, the light receiving element 22 is optically connected to the optical waveguide portion 10A.

The driving element 30 is a driving element 31 for the light emitting element 21 or a driving element 32 for the light receiving element 22, and is mounted on one surface in the thickness direction in the photoelectric conversion region R1 of the photoelectric hybrid board 10 (i.e., one surface in the thickness direction of the electric circuit board 10B). In the present embodiment, at least one driving element 31 and at least one driving element 32 are provided as the driving element 30. Specifically, the driving element 31 is an element for constituting a driving circuit for driving the light emitting element 21. Specifically, the driving element 32 is a transimpedance amplifier (TIA) for amplifying an output current from the light receiving element 22. An electrode of the driving element 30 (the driving element 31, the driving element 32) is bonded to the terminal 16b of the conductive layer 16 in the electric circuit board 10B through a bump B2 (second bump) to be electrically connected thereto. That is, the bump B2 is interposed between the photoelectric hybrid board 10 and the driving element 30 to electrically connect them. Further, the driving element 31 is electrically connected to the light emitting element 21 through the conductive layer 16. The driving element 32 is electrically connected to the light receiving element 22 through the conductive layer 16.

The thickness D2 of the driving element 30 is, for example, 50 μm or more, preferably 100 μm or more, and for example, 500 μm or less, preferably 200 μm or less. The height h2 of the bump B2 is, for example, 3 μm or more, preferably 5 μm or more, and for example, 100 μm or less, preferably 50 μm or less. The ratio (D2/h2) of the thickness D2 to the height h2 is, for example, 0.5 or more, preferably 2 or more, and for example, 150 or less, preferably 20 or less.

In the present embodiment, the thickness D2 of the driving element 30 is larger than the thickness D1 of the light-receiving/emitting element 20, while the height h2 of the bump B2 of the driving element 30 is the same as the height h1 of the bump B1 of the light-receiving/emitting element 20. Thus, the height of the driving element 30 above the photoelectric hybrid board 10 is greater than that of the light-receiving/emitting element 20.

The height H1 (=D1+h1) of the light-receiving/emitting element 20 above the photoelectric hybrid board 10 is, for example, 50 μm or more, preferably 150 μm or more, and for example, 600 μm or less, preferably 300 μm or less. The height H2 (=D2+h2) of the driving element 30 above the photoelectric hybrid board 10 is, for example, 50 μm or more, preferably 150 μm or more, and for example, 600 μm or less, preferably 300 μm or less as long as it is greater than the height H1. The value obtained by subtracting the height H1 from the height H2, that is, a difference ΔH (=H2−H1) of the height is, for example, 3 μm or more, preferably 5 μm or more, and for example, 500 μm or less, preferably 200 μm or less. Further, the ratio (H2/H1) of the height H2 to the height H1 is, for example, 1.005 or more, preferably 1.05 or more, and for example, 20 or less, preferably 4 or less.

The light emitting element 21, the light receiving element 22, the driving element 31, and the driving element 32 as described above are arranged so as to be spaced apart from each other in a plane direction above the photoelectric hybrid board 10.

The heat dissipating sheet 40 is a flexible sheet having thermal conductivity, and is in contact with the light-receiving/emitting element 20 and the driving element 30 from a side opposite to the photoelectric hybrid board 10. The heat dissipating sheet 40 is provided in a size, shape, and arrangement for including the light-receiving/emitting element 20 and the driving element 30 when projected in the thickness direction. The heat dissipating sheet 40 is interposed between a protruding portion 76 to be described later of the casing 70, and the light-receiving/emitting element 20 and the driving element 30, and is in tight contact so as to cover at least one surface in the thickness direction of the light-receiving/emitting element 20 and the driving element 30. The heat dissipating sheet 40 conducts heat generated in the light-receiving/emitting element 20 and the driving element 30 to the side of the protruding portion 76 (i.e., to the side of the casing 70), and dissipates the heat.

Examples of a constituent material for the heat dissipating sheet include resin compositions in which a filler is dispersed in a binder resin. The binder resin includes a thermosetting resin in a B-stage state or C-stage state, and may also include a thermoplastic resin. Examples of the binder resin include silicone resins, epoxy resins, acrylic resins, and urethane resins. Examples of the filler include alumina (aluminum oxide), boron nitride, zinc oxide, aluminum hydroxide, fused silica, magnesium oxide, and aluminum nitride.

The thickness T (initial thickness) of the heat dissipating sheet 40 before being assembled into the optical module X is larger than a distance between the light-receiving/emitting element 20 and the protruding portion 76 (the casing 70), and a distance between the driving element 30 and the protruding portion 76 (the casing 70), and is, for example, 200 μm or more, preferably 500 μm or more, and for example, 3000 μm or less, preferably 1500 μm or less. The ratio (ΔH/T) of the above-described difference ΔH of the height to the thickness T of the heat dissipating sheet 40 is, for example, 0.001 or more, preferably 0.005 or more, and for example, 1 or less, preferably 0.05 or less. The configuration relating to the thickness of the heat dissipating sheet 40 is suitable for ensuring followability and adhesion of the heat dissipating sheet 40 with respect to the light receiving/emitting element 20 and the driving element 30.

The Asker C hardness of the heat dissipating sheet 40 is preferably 60 or less, more preferably 55 or less, further more preferably 50 or less, and for example, 3 or more. Such a configuration is suitable for ensuring the followability and the adhesion of the heat dissipating sheet 40 with respect to the light-receiving/emitting element 20 and the driving element 30. The Asker C hardness can be measured in conformity with JIS K 7312 (1996).

As shown in FIGS. 2 and 3, the printed wiring board 50 is disposed on one side in the thickness direction of the photoelectric hybrid board 10. The printed wiring board 50 has a generally flat plate shape extending long along the longitudinal direction. As shown in FIGS. 1B, 1C, and 3, the printed wiring board 50 integrally has a first portion 51, a second portion 52, and a connecting portion 53, and also has an opening portion 54.

The first portion 51 is a one-side portion in the longitudinal direction of the printed wiring board 50. The second portion 52 is arranged to face the other side in the longitudinal direction of the first portion 51 at a distance. The width of the second portion 52 is smaller than that of the first portion 51. The connecting portion 53 connects the first portion 51 to the second portion 52. In the present embodiment, the two connecting portions 53 are provided, and one connecting portion 53 connects one end in the width direction of the other end edge in the longitudinal direction of the first portion 51 to one end in the width direction of one end edge in the longitudinal direction of the second portion 52. The other connecting portion 53 connects the other end in the width direction of the other end edge in the longitudinal direction of the first portion 51 to the other end in the width direction of one end edge in the longitudinal direction of the second portion 52.

The opening portion 54 is defined by the first portion 51, the second portion 52, and the connecting portion 53. The opening portion 54 is defined as a through hole penetrating the printed wiring board 50 in the thickness direction. In the present embodiment, in a projection view in the thickness direction, the light-receiving/emitting element 20 and the driving element 30 described above are located inside the opening portion 54. The above-described heat dissipating sheet 40, in a projection view in the thickness direction, overlaps the opening portion 54, and may be located inside the opening portion 54 or may have a portion going out of the opening portion 54 (illustratively illustrated a case of being located inside the opening portion 54).

Further, at least a portion of the periphery of the opening portion 54 in the printed wiring board 50 faces the photoelectric hybrid board 10 in the thickness direction (in FIG. 1B, the facing region is shown with hatching for clarity).

Further, the printed wiring board 50 includes a support board 55 and a conductive circuit 56. The support board 55 has a generally flat plate shape extending in the longitudinal direction (generally the same shape as the printed wiring board 50 when viewed from the top). Examples of a constituent material for the support board 55 include hard materials such as glass fiber-reinforced epoxy resins. A tensile elastic modulus at 25° C. of the support board 55 is, for example, 10 GPa or more, preferably 15 GPa or more, more preferably 20 GPa or more, and for example, 1000 GPa or less. When the tensile elastic modulus of the support board 55 is the above-described lower limit or more, excellent mechanical strength of the printed wiring board 50 is achieved.

The conductive circuit 56 includes the via 57 (shown in FIG. 3), a terminal 58 (shown in FIGS. 1B and 1C), and a wiring 59 (shown in FIG. 3).

The via 57 penetrates the support board 55 in the thickness direction. The other surface in the thickness direction of the via 57 is exposed from the support board 55, and functions as a terminal. The other surface in the thickness direction of the via 57 is electrically connected to the above-described terminal 16c through a bump B3. Thus, the printed wiring board 50 is electrically connected to the photoelectric hybrid board 10.

The terminal 58 is disposed at one end in the longitudinal direction of the first portion 51 of the printed wiring board 50. The terminal 58 is a terminal for device connection in the optical module X.

The wiring 59 is disposed on one surface in the thickness direction of the support board 55. The wiring 59 electrically connects the via 57 to the terminal 58.

The thickness of the printed wiring board 50 is larger than that of the photoelectric hybrid board 10 and is, for example, 100 μm or more, and for example, 10000 μm or less.

As shown in FIG. 3A, a gap between at least a portion of a region facing the photoelectric hybrid board 10 in the printed wiring board 50, and the photoelectric hybrid board 10 is bonded by an adhesive S. Thus, the photoelectric hybrid board 10 is fixed to the printed wiring board 50.

An anisotropic conductive film (ACF) or an anisotropic conductive paste (ACP) may be also used instead of the bump B3 and the adhesive S described above for electrical and mechanical connection between the printed wiring board 50 and the photoelectric hybrid board 10.

The connector 60A is connected to the other-side end in the longitudinal direction of the photoelectric hybrid board 10. The connector 60A is connected to the connector 60B of the optical fiber cable 100, and optically connects the optical waveguide portion 10A to an optical fiber (not shown) in the optical fiber cable 100.

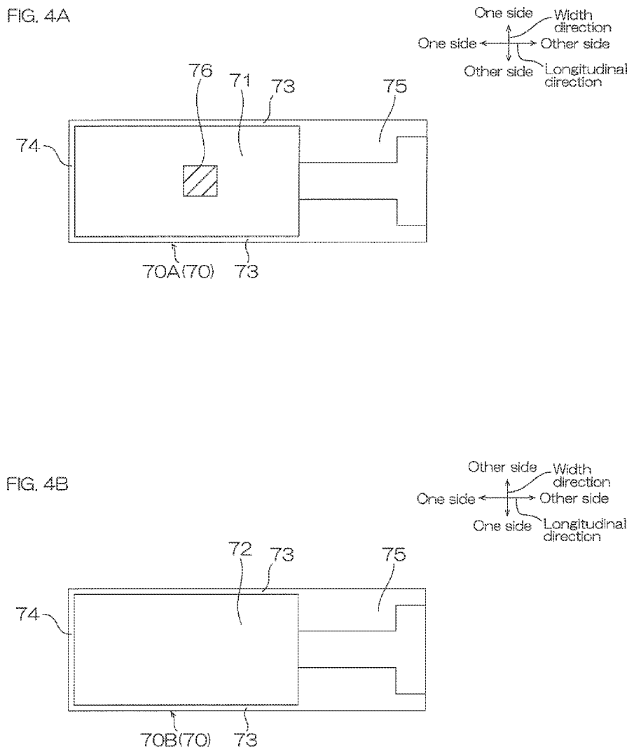

As shown in FIGS. 1B, 1C, and 2, the casing 70 has a generally box shape housing the photoelectric hybrid board 10, the light-receiving/emitting element 20, the driving element 30, the heat dissipating sheet 40, the printed wiring board 50 (excluding the terminal 58), and the connector 60A. Specifically, the casing 70 includes a first cover member 70A shown in FIG. 4A, and a second cover member 70B shown in FIG. 4B, and by assembling these, the casing 70 forms a generally flat box shape extending in the longitudinal direction and having a length in the thickness direction shorter than that in the width direction.

The casing 70 includes a first wall 71, a second wall 72, side walls 73, a longitudinal directional one-side wall 74, a longitudinal directional other-side wall 75, and the protruding portion 76.

The first wall 71 has a generally flat plate shape extending in the longitudinal direction. The second wall 72 is spaced from the first wall 71 in the thickness direction. The second wall 72 has the same shape as the first wall 71. One side wall 73 connects one end in the width direction of the first wall 71 to one end in the width direction of the second wall 72 in the thickness direction. The other side wall 73 connects the other end in the width direction of the first wall 71 to the other end in the width direction of the second wall 72 in the thickness direction. The longitudinal directional one-side wall 74 connects one ends in the longitudinal direction of the first wall 71, the second wall 72, and the side walls 73. The longitudinal directional one-side wall 74 has a hole in which the terminal 58 is disposed. The longitudinal directional other-side wall 75 connects the other ends in the longitudinal direction of the first wall 71, the second wall 72, and the side walls 73. Further, the longitudinal directional other-side wall 75 also has a hole in which the connectors 60A and 60B are disposed.

As shown in FIG. 2, the protruding portion 76 is disposed on the other side in the thickness direction of the first wall 71, protrudes from the first wall 71 toward the photoelectric hybrid board 10, and partially enters the opening portion 54 (the protruding portion 76 is included in the opening portion 54 when projected in the thickness direction). In the present embodiment, the protruding portion 76 has a generally thick flat plate shape. In FIG. 4A, the protruding portion 76 is shown with hatching in order to clearly show the relative arrangement and the shape of the protruding portion 76 with respect to the first wall 71. Further, in the present embodiment, the protruding portion 76 and the first wall 71 are integrated. The other surface in the thickness direction of the protruding portion 76 is in tight contact with one surface in the thickness direction of the heat dissipating sheet 40, and presses the heat dissipating sheet 40 toward the light-receiving/emitting element 20 and the driving element 30.

The first wall 71 and the protruding portion 76 are included in the first cover member 70A. Each of the side walls 73 is included in both the first cover member 70A and the second cover member 70B. The longitudinal directional one-side wall 74 is included in both the first cover member 70A and the second cover member 70B. The longitudinal directional other-side wall 75 is included in both the first cover member 70A and the second cover member 70B.

The casing 70 is made of metal in the present embodiment. Examples of a metal material for the casing 70 include aluminum, copper, silver, zinc, nickel, chromium, titanium, tantalum, platinum, gold, and alloys of these. The casing 70 may be also subjected to surface treatment such as plating.

The optical module X is, for example, obtained as follows. First, the light-receiving/emitting element 20 and the driving element 30 are mounted on the electric circuit board 10B of the photoelectric hybrid board 10. For example, the light-receiving/emitting element 20 is connected to the terminal 16a in the electric circuit board 10B through the bump B1 formed in advance on an electrode thereof, and the driving element 30 is bonded to the terminal 16b in the electric circuit board 10B through the bump B2 formed in advance on the electrode thereof. Next, the photoelectric hybrid board 10 is bonded to the printed wiring board 50 through the adhesive S (the light-receiving/emitting element 20 and the driving element 30 are disposed inside the opening portion 54 of the printed wiring board 50). For example, the photoelectric hybrid board 10 is bonded to the printed wiring board 50 by the adhesive S applied so as to surround the bump B3, while the printed wiring board 50 and the photoelectric hybrid board 10 are electrically connected through the bump B3 formed in advance on the other surface in the thickness direction of the via 57 in the printed wiring board 50 (thus, the wiring 59 in the printed wiring board 50 is electrically connected to the conductive layer 16 in the photoelectric hybrid board 10 through the via 57). Next, the optical waveguide portion 10A of the photoelectric hybrid board 10 is connected to the connector 60A. Next, the photoelectric hybrid board 10, the printed wiring board 50, and the connector 60A are disposed on the second cover member 70B of the casing 70. Next, the heat dissipating sheet 40 is disposed in lamination on the light-receiving/emitting element 20 and the driving element 30 on the photoelectric hybrid board 10. Next, the casing 70 is formed by adjusting the first cover member 70A to the second cover member 70B. Specifically, the first cover member 70A is adjusted to the second cover member 70B so that the other-side portion in the thickness direction of the protruding portion 76 in the first cover member 70A is inserted into the opening portion 54, and the other surface in the thickness direction of the protruding portion 76 is brought into contact with the heat dissipating sheet 40. Thus, the heat dissipating sheet 40 is pressed in the thickness direction, and is in tight contact with the light-receiving/emitting element 20 and the driving element 30. Thereafter, the connector 60A located inside the casing 70 is connected to the connector 60B of the optical fiber cable 100. For example, as described above, the optical module X is obtained.

When the optical module X is used, the terminal 58 of the optical module X is inserted into a receptacle of an electronic device (not shown).

Next, conversion from an electrical signal to the optical signal in the optical module X is described. The electrical signal is input from an electronic device (not shown) into the optical module X through the terminal 58. The electrical signal flows through the conductive circuit 56 of the printed wiring board 50 and is further input into the driving element 31 via the conductive layer 16 in the photoelectric hybrid board 10. The driving element 31 to which the electrical signal is input drives the light emitting element 21 to emit light. Specifically, the light emitting element 21 emits light from a light emitting port toward the mirror surface 12m of the core layer 12. An optical path of the light is changed at the mirror surface 12m of the core layer 12 in the optical waveguide portion 10A, and the light travels inside the core layer 12 along its extending direction. Thereafter, the light is input as an optical signal into the optical fiber cable 100 through the connectors 60A and 60B.

Subsequently, the conversion from the optical signal to the electrical signal in the optical module X is described. The optical signal enters the optical waveguide portion 10A through the connectors 60A and 60B from the optical fiber cable 100, and the optical path thereof is changed at the mirror surface 12m. The optical signal is then received through the light receiving port at the light receiving element 22, and is converted to an electrical signal at the light receiving element 22. On the other hand, the driving element 32 amplifies the electrical signal converted at the light receiving element 22 based on the electricity (electric power) supplied from the printed wiring board 50. The amplified electrical signal flows through the conductive circuit 56 of the printed wiring board 50 through the conductive layer 16, and is input into an electronic device (not shown) through the terminal 58.

The light-receiving/emitting element 20 (the light emitting element 21, the light receiving element 22) and the driving element 30 (the driving element 31, the driving element 32) generate heat due to mutual conversion between the electrical signal and the optical signal as described above.

In the optical module X, as described above, the heat dissipating sheet 40 contacts the light-receiving/emitting element 20 and the driving element 30 mounted above one surface in the thickness direction of the photoelectric hybrid board 10 from the side opposite to the photoelectric hybrid board 10. Such a configuration is suitable for releasing the heat generated in the light-receiving/emitting element 20 and the driving element 30 to the outside the element by the heat dissipating sheet 40, and accordingly, outside the optical module X through the heat dissipating sheet 40 and the casing 70. Then, in the optical module X, as described above, the height H2 of the driving element 30 is greater than the height H1 of the light-receiving/emitting element 20 above the photoelectric hybrid board 10. Therefore, the pressing force of the heat dissipating sheet 40, which is pressed by the light-receiving/emitting element 20 and the driving element 30 in the casing 70, is relatively strong with respect to the driving element 30, and relatively weak with respect to the light-receiving/emitting element 20. Such a configuration is suitable for realizing heat dissipation of the light-receiving/emitting element 20 by the heat dissipating sheet 40 while suppressing damage to the light-receiving/emitting element 20, and for realizing a high heat dissipation efficiency with the driving element 30 by the heat dissipating sheet 40. That is, the optical module X is suitable for realizing excellent heat dissipation of the light-receiving/emitting element 20 and the driving element 30 while suppressing damage to the light-receiving/emitting element 20. Further, in the above-described embodiment, the metal support layer 14 made of metal also has heat dissipation, and the metal support layer 14 exhibits a heat dissipating function in cooperation with the heat dissipating sheet 40 during operation of the optical module X.

The Asker C hardness of the heat dissipating sheet 40 in the optical module X is preferably 60 or less, more preferably 55 or less, further more preferably 50 or less. The heat dissipating sheet 40 having such a degree of softness is suitable for ensuring the followability and the adhesion with respect to the light-receiving/emitting element 20 and the driving element 30 which have different heights above the photoelectric hybrid board 10, and accordingly, suitable for realizing both damage suppression of the light-receiving/emitting element 20 and a high heat dissipation efficiency for the driving element 30.

In the following, modified examples are described. In each modified example, the same reference numerals are provided for members corresponding to each of those in the above-described embodiment, and their detailed description is omitted. Each modified example can achieve the same function and effect as that of the above-described embodiment unless otherwise specified. Furthermore, the above-described embodiment and the modified example thereof can be appropriately used in combination.

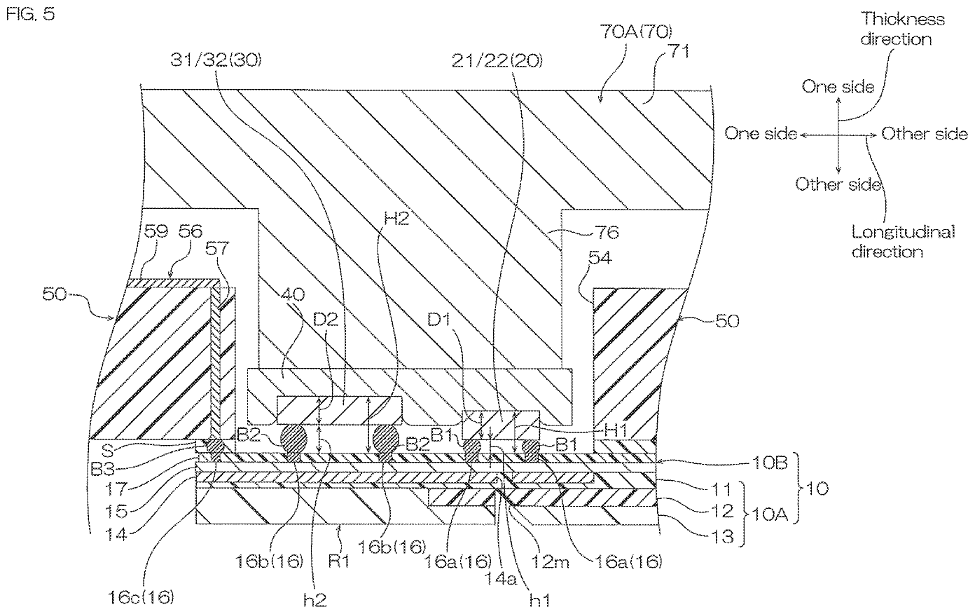

In the modified example shown in FIG. 5, the bump B2 of the driving element 30 is higher than the bump B1 of the light-receiving/emitting element 20 on the photoelectric hybrid board 10. That is, the bump B2 interposed between the photoelectric hybrid board 10 and the driving element 30 has a greater height above the photoelectric hybrid board 10 than the bump B1 interposed between the photoelectric hybrid board 10 and the light-receiving/emitting element 20.

In the modified example, the height h2 of the bump B2 is greater than the height h1 of the bump B1, while the thickness D1 of the light-receiving/emitting element 20 is, for example, the same as the thickness D2 of the driving element 30. Thus, the height of the driving element 30 is greater than the light-receiving/emitting element 20 above the photoelectric hybrid board 10.

A value obtained by subtracting the height h1 of the bump B1 from the height h2 of the bump B2, that is, the difference Δh (=h2−h1) of the height is, for example, 3 μm or more, preferably 5 μm or more, and for example, 100 μm or less, preferably 50 μm or less. Further, the ratio (h2/h1) of the height h2 to the height h1 is, for example, 1.01 or more, preferably 1.03 or more, and for example, 30 or less, preferably 3 or less.

The configuration of the modified example is suitable for adjusting the heights H1 and H2 of the light-receiving/emitting element 20 and the driving element 30 above the photoelectric hybrid board 10 at a higher degree of freedom depending on the heights h1 and h2 of the bumps B1 and B2 regardless of the thicknesses D1 and D2 of the light-receiving/emitting element 20 and the driving element 30. The configuration is suitable for making the height H2 of the driving element 30 greater than the height H1 of the light-receiving/emitting element 20 above the photoelectric hybrid board 10, even though the thickness D1 of the light-receiving/emitting element 20 is the thickness D2 of the driving element 30 or more.

In the above-described embodiment and modified example, the protruding portion 76 and the first wall 71 are integrated. However, the protruding portion 76 and the first wall 71 may be separated. The protruding portion 76 which is separated from the first wall 71 is fixed to the other surface in the thickness direction of the first wall 71 through, for example, an adhesive. As a constituent material for the protruding portion 76, the above-described metal material using the casing 70 as a constituent material is preferably used. As a constituent material for the protruding portion 76, a thermally conductive resin composition may be also used.

The embodiment in which the protruding portion 76 and the first wall 71 are integrated is more preferable than the modified example. In the modified example, since the thermal conductivity of the adhesive is lower than that of the first wall 71 and the protruding portion 76, the heat dissipation from the protruding portion 76 to the first wall 71 is low. On the other hand, in the embodiment in which the protruding portion 76 and the first wall 71 are integrated, since the protruding portion 76 and the first wall 71 are integrated, it is not necessary to dispose the adhesive, and excellent heat dissipation from the protruding portion 76 to the first wall 71 is achieved. Further, the embodiment in which the protruding portion 76 and the first wall 71 are integrated without the adhesive is preferable from the viewpoint of a reduction in the number of components and simplification of the configuration.

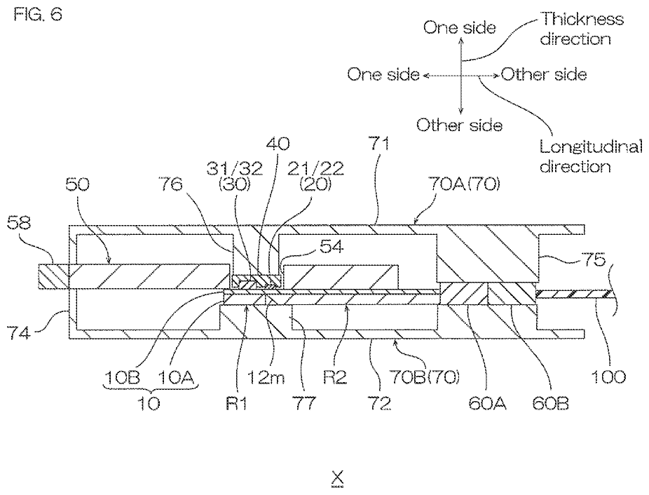

In the modified example shown in FIG. 6, the optical module X further includes a protruding portion 77 in contact with the other surface in the thickness direction of the photoelectric hybrid board 10 (the surface opposite to the light-receiving/emitting element 20 and the driving element 30). The protruding portion 77 is disposed on one side in the thickness direction of the second wall 72, and protrudes from the second wall 72 toward the photoelectric hybrid board 10. The protruding portion 77 and the second wall 72 are integrated. One surface in the thickness direction of the protruding portion 77 is in contact with and supports the other surface in the thickness direction of the photoelectric hybrid board 10. The second wall 72 is disposed at the side opposite to the photoelectric hybrid board 10 in the thickness direction with respect to the protruding portion 77.

In the modified example, it is also possible to dissipate the heat to the side of the second wall 72 through the bumps B1 and B2, the photoelectric hybrid board 10, and the protruding portion 77 in addition to the dissipation of the heat generated in the light-receiving/emitting element 20 and the driving element 30 to the side of the first wall 71 through the heat dissipating sheet 40 and the protruding portion 76.

On the other hand, though not shown, the protruding portion 77 may be separated from the second wall 72. The protruding portion 77 which is separated from the second wall 72 is fixed to one surface in the thickness direction of the second wall 72 through an adhesive which is not shown. As a constituent material for the protruding portion 77, the above-described metal material using the casing 70 as a constituent material is preferably used. As a constituent material for the protruding portion 77, a thermally conductive resin composition may be also used.

Preferably, the protruding portion 77 and the second wall 72 are integrated. In the embodiment in which the protruding portion 77 and the second wall 72 are integrated, since the protruding portion 77 and the second wall 72 are integrated, it is not necessary to dispose the adhesive for bonding them, and excellent heat dissipation from the protruding portion 77 to the second wall 72 is achieved. Further, the embodiment in which the protruding portion 77 and the second wall 72 are integrated without the adhesive is preferable from the viewpoint of a reduction in the number of components and simplification of the configuration.

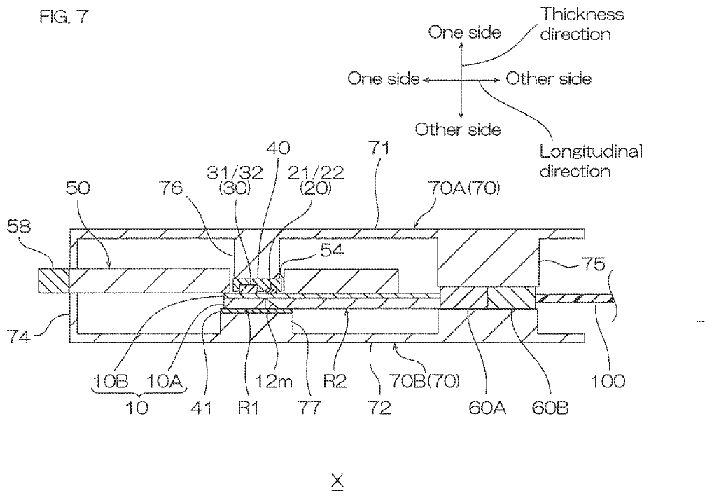

In the modified example shown in FIG. 7, the optical module X further includes a heat dissipating layer 41 interposed between the above-described protruding portion 77 and the photoelectric hybrid board 10.

The heat dissipating layer 41 is disposed on the entire one surface in the thickness direction of the protruding portion 77. The heat dissipating layer 41 contacts the other surface in the thickness direction of the photoelectric conversion region R1 of the photoelectric hybrid board 10, and one surface in the thickness direction of the protruding portion 77. Examples of the heat dissipating layer 41 include heat dissipating sheets, heat dissipating grease, and heat dissipating boards. When the heat dissipating layer 41 is a heat dissipating sheet, as a constituent material, the above-described constituent material for the heat dissipating sheet 40 is used.

Since the modified example further includes the heat dissipating layer 41, it is also possible to efficiently dissipate the heat to the side of the second wall 72 through the bumps B1 and B2, the photoelectric hybrid board 10, the heat dissipating layer 41, and the protruding portion 77 in addition to the heat dissipation of the heat generated in the light-receiving/emitting element 20 and the driving element 30 to the side of the first wall 71 through the heat dissipating sheet 40 and the protruding portion 76.

In the above-described optical module X, when the thickness D1 of the light-receiving/emitting element 20 and the thickness D2 of the driving element 30 are the same (i.e., for example, as shown in FIG. 5, a case of D1=D2), by making the height h2 of the bump B2 of the driving element 30 greater than the height h1 of the bump B1 of the light-receiving/emitting element 20, the height H2 of the driving element 30 becomes greater than the height H1 of the light-receiving/emitting element 20. A configuration using the light-receiving/emitting element 20 and the driving element 30 having the same thicknesses is preferable, for example, from the viewpoint of easy procurement of the light-receiving/emitting element 20 and the driving element 30 which may have the element size standardized and the thickness unified.

In the optical module X, when the thickness D2 of the driving element 30 is larger than the thickness D1 of the light-receiving/emitting element 20 (i.e., a case of D1<D2), by providing the bumps B1 and B2 (including the bumps B1 and B2 shown in FIG. 3 satisfying h1=h2, and the bumps B1 and B2 satisfying h2>h1) satisfying the conditions in which a value obtained by subtracting the height h2 of the bump B2 from the height h1 of the bump B1, that is, the difference Δh′ (=h1−h2) of the height is smaller than the difference ΔD (=D2−D1) of the thickness therebetween, the height H2 of the driving element 30 is made greater than the height H1 of the light-receiving/emitting element 20. A configuration in which the thickness D1 is thinner than the thickness D2, and the height H2 is greater than the height H1 is suitable for suppressing damage to the light-receiving/emitting element 20 and realizing excellent heat dissipation of elements regardless of the fact that the light-receiving/emitting element 20 which tends to be more fragile and more easily damaged than the driving element 30 is thinner than the driving element 30.

In the optical module X, when the thickness D2 of the driving element 30 is thinner than the thickness D1 of the light-receiving/emitting element 20 (i.e., a case of D1>D2), the height H2 of the driving element 30 is made greater than the height H1 of the light-receiving/emitting element 20 by providing the bumps B1 and B2 satisfying the conditions in which the above-described difference Δh (=h2−h1) of the height of the bumps B1 and B2 is larger than the difference ΔD′ (=D1−D2) of the thickness. A configuration in which the thickness D1 is larger than the thickness D2, and the height H2 is greater than the height H1 is suitable for realizing excellent heat dissipation of elements while suppressing damage to the light-receiving/emitting element 20 which tends to be more fragile and more easily damaged than the driving element 30.

As described above, the optical module X shown in FIGS. 1A to 3 is configured as a transmitting and receiving module (i.e., an optical transceiver) having both a transmission function of converting an electrical signal from a device to an optical signal and outputting it to the optical fiber cable 100, and a receiving function of converting an optical signal from the optical fiber cable 100 to an electrical signal and outputting it to a device. Alternatively, the optical module X may also include a configuration having a transmission function without having a receiving function. In such an optical module X, the light emitting element 21 is mounted on the photoelectric hybrid board 10 as the light-receiving/emitting element 20, and the driving element 31 for the light emitting element 21 is mounted on the photoelectric hybrid board 10 as the driving element 30. Alternatively, the optical module X may also have a configuration having a receiving function without having a transmission function. In such an optical module X, the light receiving element 22 is mounted on the photoelectric hybrid board 10 as the light-receiving/emitting element 20, and the driving element 32 for the light receiving element 22 is mounted on the photoelectric hybrid board 10 as the driving element 30.

### INDUSTRIAL APPLICATION

The photoelectric conversion module of the present invention is, for example, applicable to optical transceivers, optical transmitting modules, and optical receiving modules in an optical transmission system.

### DESCRIPTION OF REFERENCE NUMERALS

X Optical module (photoelectric conversion module)

10 Photoelectric hybrid board

10A Optical waveguide portion

11 Under-cladding layer

12 Core layer

13 Over-cladding layer

10B Electric circuit board

14 Metal support layer

20 Light-receiving/emitting element

21 Light emitting element

22 Light receiving element

30, 31, 32 Driving element

B1, B2 Bump

40 Heat dissipating sheet

41 Heat dissipating layer

50 Printed wiring board

60A, 60B Connector

70 Casing

70A First cover member

70B Second cover member

76, 77 Protruding portion

1. A photoelectric conversion module comprising:
a photoelectric hybrid board;
a light-receiving/emitting element and a driving element mounted on one surface in a thickness direction of the photoelectric hybrid board; and
a heat dissipating sheet contacting the light-receiving/emitting element and the driving element from a side opposite to the photoelectric hybrid board,
wherein the driving element has a greater height above the photoelectric hybrid board than the light-receiving/emitting element.

2. The photoelectric conversion module according to claim 1, further comprising:
a first bump interposed between the photoelectric hybrid board and the light-receiving/emitting element and electrically connecting them, and
a second bump interposed between the photoelectric hybrid board and the driving element and electrically connecting them,
wherein the second bump has a greater height above the photoelectric hybrid board than the first bump.

3. The photoelectric conversion module according to claim 1, wherein the heat dissipating sheet has an Asker C hardness of 60 or less.
